(19) United States
(12) Patent Application Publication
(10) Pub. No.: US 2026/0024599 A1
(43) Pub. Date: Jan. 22, 2026

(54) EFUSE MEMORY CELL AND MEMORY ARRAY

(71) Applicant: Shanghai Huali Integrated Circuit Corporation, Shanghai (CN)

(72) Inventor: Ying YAN, Shanghai (CN)

(73) Assignee: Shanghai Huali Integrated Circuit Corporation, Shanghai (CN)

(21) Appl. No.: 19/089,428

(22) Filed: Mar. 25, 2025

(30) Foreign Application Priority Data
Jul. 19, 2024 (CN) 202410979550.6

(51) Int. Cl. G11C 17/16

(52) U.S. Cl. CPC G11C 17/16

(57) ABSTRACT

The present disclosure discloses an eFuse memory cell, which comprises a first selection transistor, a second selection transistor and a fuse-link, wherein a gate terminal of the first selection transistor is used as a BL port, a drain terminal of the first selection transistor is used as a Q port, and a source terminal of the first selection transistor is connected to a drain terminal of the second selection transistor as a SA port; a gate terminal of the second selection transistor is used as a WL port, and a source terminal of the second selection transistor is connected to one end of the fuse-link; the other end of the fuse-link is used as a gnd port. The present disclosure further discloses an eFuse memory array consisting of the eFuse memory cells.

### CROSS-REFERENCE TO RELATED APPLICATIONS

This application claims priority to Chinese patent application No. 202410979550.6, filed on Jul. 19, 2024, the disclosure of which is incorporated herein by reference in its entirety.

### TECHNICAL FIELD

The present disclosure relates to semiconductor storage technology, in particular to an eFuse (electronic fuse) memory cell and a memory array.

### BACKGROUND

As a one-time programmable memory, eFuse memory is widely used in chips. eFuse memory realizes a programming function by means of electromigration or fusing when the current flows through a fuse-link. The storage capacity, programming current and chip area of eFuse memory are the main indicators. The storage capacity is determined by the array of memory cells inside the eFuse memory. Each eFuse memory cell consists of MOS selection transistors and a fuse-link, and the MOS selection transistors occupy a major part of the overall area of the eFuse memory cell. A MOS transistor manufactured through a conventional process has a substrate bias effect (i.e., a body-effect), which reduces the current capacity of the transistor. Therefore, in order to ensure sufficient programming current capacity, MOS selection transistors are often large in size.

A conventional eFuse memory cell, as shown in FIG. 1, consists of an NMOS selection transistor Mn and a fuse-link. A selection control signal WL is connected to a gate terminal of the NMOS selection transistor Mn.

As shown in FIG. 2, a memory array consisting of the conventional eFuse memory cells comprises power control tubes Mpn, eFuse cells, bit line control signals BLCn and word line control signals WLn; the VDDQ is a programming power supply, and the power control tube Mpn is a PMOS tube, with its gate terminal connected to the bit line control signal BLCn and its drain terminal connected to the bit line BLn, and each bit line is connected to a sense amplifier (SA). The word line control signal WLn is connected to the gate terminals of the selection transistors (programming control tubes) of the eFuse cells in each row. In the eFuse memory array shown in FIG. 2, PMOS tubes are used to control the programming current flowing through all the memory cells in each column of bit lines. In order to ensure the programming reliability, a sufficient programming current is required to flow through the fuse-link of each memory cell. Therefore, the PMOS tube is large in size, and the driving circuit corresponding to the PMOS tube is also large in size.

FIG. 3 is a driving circuit diagram of a memory array consisting of the conventional eFuse memory cells. The driving circuits of the memory cells in the rows and columns are different, and power control tubes Mp1 are required to provide the programming currents required by the memory cells in corresponding bit lines BL1. The power control tubes are large in size, and the driving capability of corresponding bit line driving modules (P-buffers) should be stronger than that of the word line driving modules (N-buffers).

FIG. 4 is a schematic diagram illustrating the three-dimensional structure of the memory array consisting of conventional eFuse memory cells. A bit line BL is used as a programming current path for the memory cells connected to the bit line, and the programming current of each memory cell must flow through the bit line BL; therefore, the programming current of the eFuse memory cells in the same column may be easily affected by a voltage drop (IR-drop) formed in the bit line.

As shown in FIG. 5, when two memory cells located at (WL1, BL1) and (WLn, BLn) respectively are programmed, different voltage drop (IR-drop) effects will occur owing to the difference in the lengths of the bit lines reaching the eFuse memory cells in different rows, which is to say, the eFuse memory cells in different rows are at different distances from the programming power supply VDDQ (the lengths of the bit lines through which the current flows).

### BRIEF SUMMARY

The present disclosure provides an eFuse memory cell, which comprises a first selection transistor Mn1, a second selection transistor Mn2 and a fuse-link, wherein
a gate terminal of the first selection transistor Mn1 is used as a BL port;
a drain terminal of the first selection transistor Mn1 is used as a Q port;
a source terminal of the first selection transistor Mn1 is connected to a drain terminal of the second selection transistor Mn2 as a SA port;
a gate terminal of the second selection transistor Mn2 is used as a WL port;
a source of the second selection transistor Mn2 is connected to one end of the fuse-link; and
the other end of the fuse-link is used as a gnd port.

Preferably, the BL port is used for connecting a bit line BL;
the Q port is used for connecting a programming power supply VDDQ;
the SA port is used for connecting a sense amplifier SA;
the WL port is used for connecting a word line WL; and
the gnd port is used for grounding.

Preferably, the first selection transistor Mn1 and the second selection transistor Mn2 are NMOS tubes.

Preferably, substrate terminals of the first selection transistor Mn1 and the second selection transistor Mn2 are short-circuited to their respective source terminals.

Preferably, the first selection transistor Mn1 and the second selection transistor Mn2 have the same size and structure.

Preferably, the first selection transistor Mn1 and the second selection transistor Mn2 in the eFuse memory cell are manufactured through a Gate-All-Around (GAA) process.

A memory array consisting of the eFuse memory cells, comprising m rows and n columns of eFuse memory cells, where m and n are positive integers, wherein
the Q ports of all eFuse memory cells are connected to the same programming power supply VDDQ;
the WL ports of the eFuse memory cells in the same row are connected to the same word line WL;
the BL ports of the eFuse memory cells in the same column are connected to the same bit line BL; and
the SA ports of the eFuse memory cells in the same column are connected together and connected to corresponding sense amplifiers SA.

Preferably, m and n are greater than 1.

Preferably, m is equal to 2 R, n is equal to 2 Q, and R and Q are positive integers.

The eFuse memory cell in the present disclosure consists of two identical NMOS selection transistors (Mn1 and Mn2) and a fuse-link, forming a five-port device (Q, BL, WL, SA, gnd). An eFuse memory array consisting of the eFuse memory cells can prevent the programming currents of the eFuse memory cells on the same bit line from being affected by a voltage drop (IR-drop) owing to the difference in bit line length at the positions, simplify the circuit and layout design, reduce the overall area and improve the reliability.

### BRIEF DESCRIPTION OF THE DRAWINGS

To explain the technical scheme in the embodiments of the present disclosure more clearly, the drawings to be used in the description of the present disclosure will be introduced below briefly. Obviously, the drawings used in the description below only illustrate some embodiments of the present disclosure, and those having ordinary skills in the art can work out other drawings based on these drawings without expending any creative labor.

FIG. 1 is a circuit diagram of a conventional eFuse memory cell;

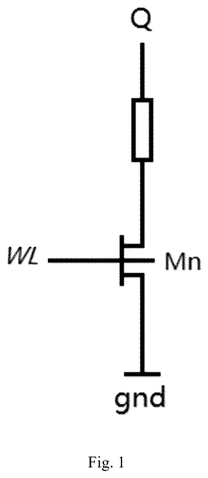

FIG. 2 is a cell array consisting of conventional eFuse memory cells;

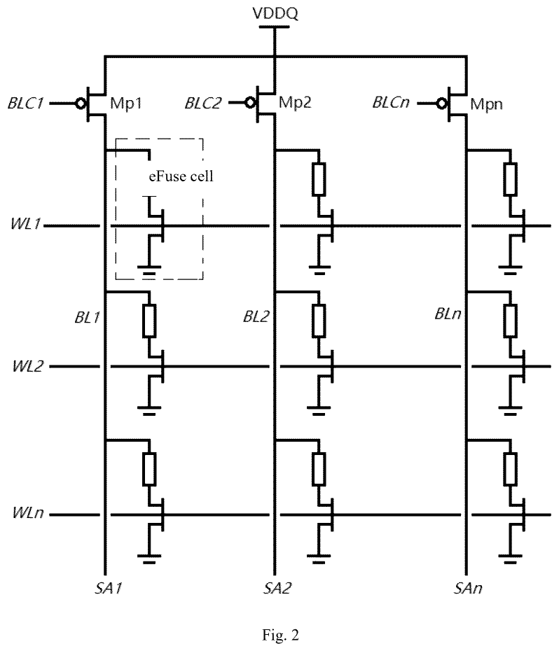

FIG. 3 is a driving circuit diagram of a memory array consisting of conventional eFuse memory cells;

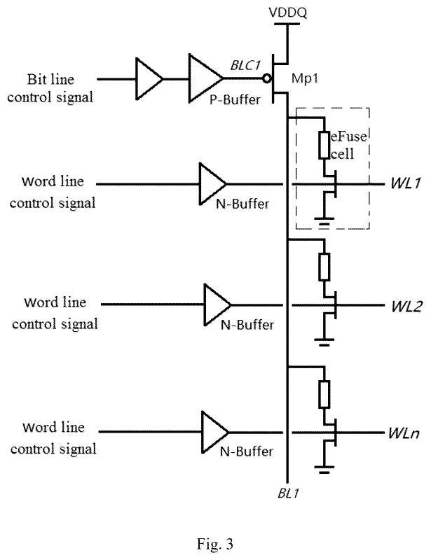

FIG. 4 is a schematic diagram illustrating the three-dimensional structure of a memory array consisting of conventional eFuse memory cells;

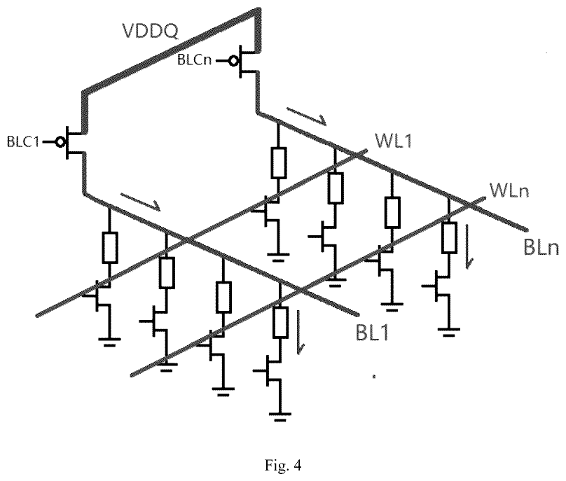

FIG. 5 shows a voltage drop (IR-drop) formed in a bit line by the cell programming current of a memory array consisting of conventional eFuse memory cells;

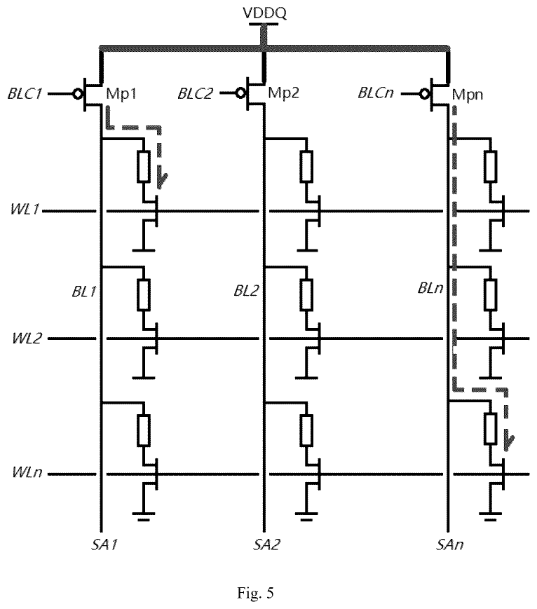

FIG. 6 is a circuit diagram of an embodiment of the eFuse memory cell in the present disclosure;

FIG. 7 is a circuit diagram of an embodiment of the eFuse memory array in the present disclosure;

FIG. 8 is a schematic diagram illustrating the programming of an embodiment of the eFuse memory array in the present disclosure;

FIG. 9 is a schematic diagram illustrating a read operation of an embodiment of the eFuse memory array in the present disclosure;

FIG. 10 is a schematic diagram illustrating the three-dimensional structure of an embodiment of the eFuse memory array in the present disclosure;

FIG. 11 shows that the cell programming current of an embodiment of the eFuse memory array in the present disclosure has no voltage drop (IR-drop) effect on the bit line;

FIG. 12 is a driving circuit diagram of an embodiment of the eFuse memory array in the present disclosure.

### DETAILED DESCRIPTION OF THE DISCLOSURE

The technical scheme in the embodiments of the present disclosure will be detailed below clearly and completely with reference to the accompanying drawings of the embodiments. Obviously, the embodiments described herein are only some embodiments of the present disclosure, not all possible embodiments of the present disclosure. Those having ordinary skills in the art can obtain other embodiments based on the embodiments described herein without expending any creative labor; however, all such embodiments shall be deemed to fall within in the scope of protection of the present disclosure.

In addition, the words “first,” “second,” and the like used in the present application do not indicate any order, quantity or importance, but are only used to distinguish different parts. “Comprising” or “including” or the like means that the elements or objects appearing before the word encompass the elements or objects enumerated after the word and their equivalents, without excluding other elements or objects. “Connecting” or “connected” or the like is not limited to a physical or mechanical connection, but can include an electrical connection, regardless of whether the electrical connection is a direct one or an indirect one. “Top,” “bottom,” “left,” “right,” “front,” and “back,” etc., are only intended to express a relative positional relationship, which may change accordingly as the absolute position of the described object changes.

It should be noted that the embodiments in the present disclosure and the features in the embodiments can be combined with each other, provided that there is no conflict among them.

### Embodiment 1

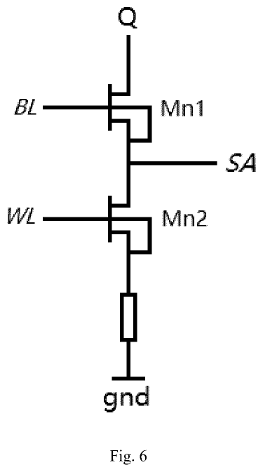

As shown in FIG. 6, an eFuse memory cell comprises a first selection transistor Mn1, a second selection transistor Mn2 and a fuse-link;
a gate terminal of the first selection transistor Mn1 is used as a BL port;
a drain terminal of the first selection transistor Mn1 is used as a Q port;
a source terminal of the first selection transistor Mn1 is connected to a drain terminal of the second selection transistor Mn2 as a SA port;
a gate terminal of the second selection transistor Mn2 is used as a WL port;
a source of the second selection transistor Mn2 is connected to one end of the fuse-link; and
the other end of the fuse-link is used as a gnd port.
The BL port is used for connecting a bit line BL;
the Q port is used for connecting a programming power supply VDDQ;
the SA port is used for connecting a sense amplifier (SA);
the WL port is used for connecting a word line WL; and
the gnd port is used for grounding.

Preferably, the first selection transistor Mn1 and the second selection transistor Mn2 are NMOS tubes.

Preferably, substrate terminals of the first selection transistor Mn1 and the second selection transistor Mn2 are short-circuited to their respective source terminals.

Preferably, the first selection transistor Mn1 and the second selection transistor Mn2 have the same size, structure and electrical properties.

The eFuse memory cell in the Embodiment 1 consists of two identical NMOS selection transistors (Mn1 and Mn2) and a fuse-link, forming a five-port device (Q, BL, WL, SA, gnd). An eFuse memory array consisting of the eFuse memory cells can prevent the programming currents of the eFuse memory cells on the same bit line from being affected by a voltage drop (IR-drop) owing to the difference in bit line length at the positions, simplify the circuit and layout design, reduce the overall area and improve the reliability.

### Embodiment 2

Based on the eFuse memory cell in the Embodiment 1, the first selection transistor Mn1 and the second selection transistor Mn2 in the eFuse memory cell are manufactured through a Gate-All-Around (GAA) process.

Since a MOS transistor manufactured through a Gate-All-Around (GAA) process is not affected by a substrate bias effect (i.e., body-effect), it is equivalent to that the substrate terminals of the NMOS transistors (Mn1 and Mn2) are connected to the source terminals of the respective NMOS transistors.

The Gate-All-Around (GAA) process employs a nanowire channel design, in which the entire channel of a MOS tube is fully surrounded by the gate. Since the gate surrounds the entire channel of the MOS tube, a bias effect of the current flowing through the MOS tube is eliminated. Therefore, the gate of a MOS tube manufactured through a GAA process has better channel control performance and better electrical indexes, and can meet the requirement for smaller gate width. In the same size, a MOS transistor manufactured through a GAA process has enhanced channel control ability, improved current flow capacity, reduced cut-off current, making it possible to further reduce chip size.

In the eFuse memory cell in the Embodiment 2, the first selection transistor Mn1 and the second selection transistor Mn2 are manufactured through a Gate-All-Around (GAA) process, which can reduce the area of the eFuse memory cell and improve the current flow capacity and programming reliability.

### Embodiment 3

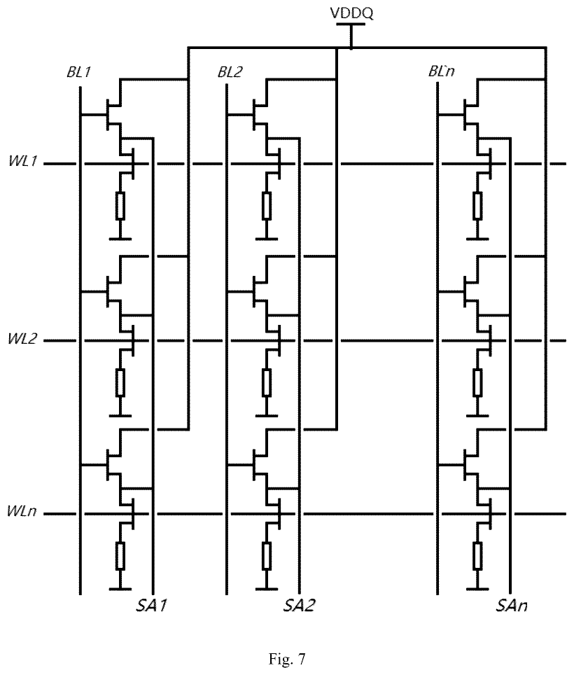

A memory array consisting of the eFuse memory cells in the Embodiment 1, as shown in FIG. 7, comprises m rows and n columns of eFuse memory cells, where m and n are positive integers, wherein
the Q ports of all eFuse memory cells are connected to the same programming power supply VDDQ;
the WL ports of the eFuse memory cells in the same row are connected to the same word line WL;
the BL ports of the eFuse memory cells in the same column are connected to the same bit line BL; and
the SA ports of the eFuse memory cells in the same column are connected together and connected to corresponding sense amplifiers SA.

Preferably, m and n are greater than 1.

Preferably, m is equal to 2 R, n is equal to 2 Q, and R and Q are positive integers.

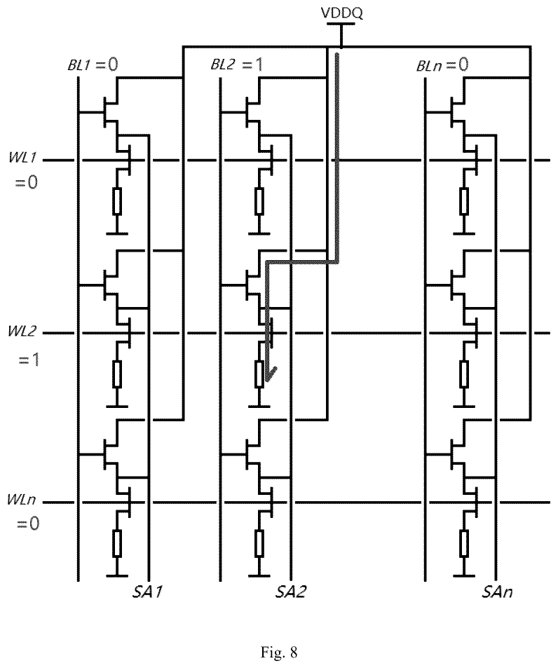

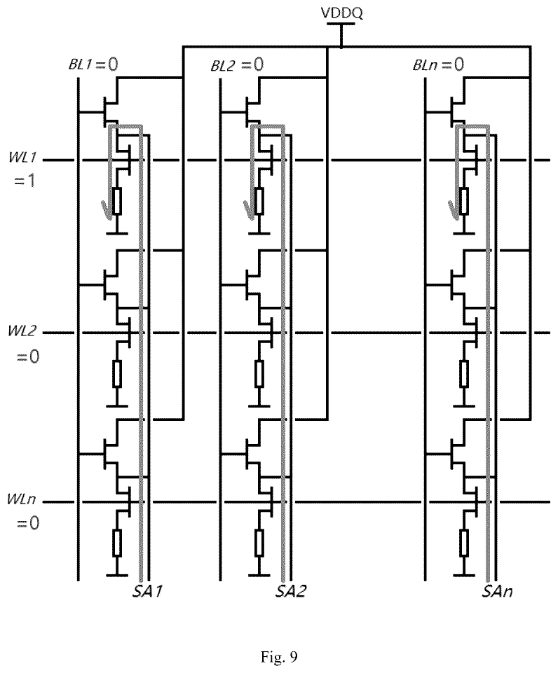

In the eFuse memory array in the Embodiment 3, the programming operation of the eFuse cells is shown in FIG. 8, in which the second word line WL2 and the second bit line BL2 are set to high level, while other control signals are set to low level, and the programming current flows through the eFuse memory cell in the second row and the second column in the array to program the memory cell; in a reading operation of the eFuse memory cells, as shown in FIG. 9, the first word line WL1 is set to high level, while all other signals are set to low level; the reading currents from all sense amplifiers SA flow through all eFuse cells in the first row in the array to read the memory cells in that row.

In the eFuse memory array in the Embodiment 3, instead of using PMOS transistors in the bit lines to control the gating operation and programming current, the bit line control function is implemented in each memory cell, and two identical NMOS selection transistors are used in the eFuse memory cell to control the gating of the eFuse memory cell in the bit lines (Y direction) and word lines (X direction) in the array respectively.

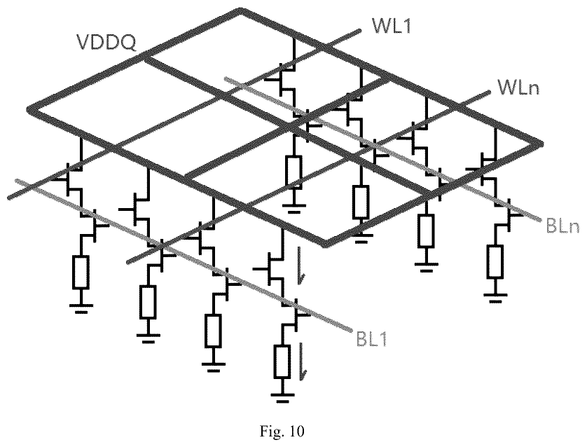

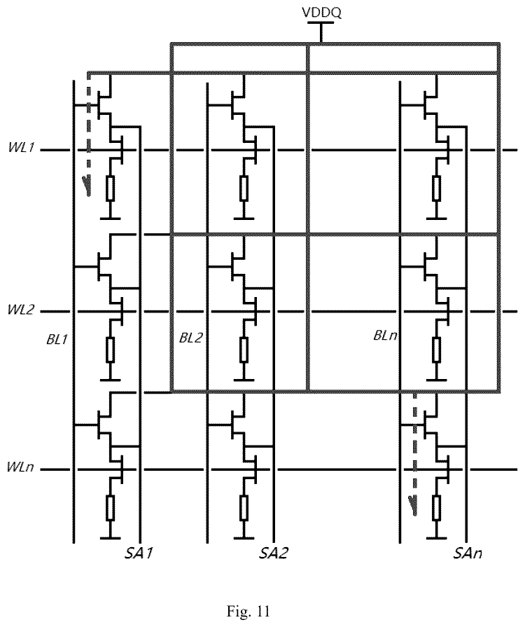

As shown in FIG. 10, in the eFuse memory array in the Embodiment 3, the Q ports of all eFuse memory cells are directly connected to the programming voltage VDDQ, and the bit lines BL serve as the bit gating control signal lines for the memory cells and are connected to the gate terminals of respective memory cells. The programming current for each memory cell is directly led from the programming power supply VDDQ, and the programming current for each eFuse memory cell doesn't flow through the bit line BL, thus avoiding that the programming current for each eFuse memory cell in the same bit line may be easily affected by voltage drop (IR-drop) due to the difference in bit line length. As shown in FIG. 11, two memory cells located at (WL1, BL1) and (WLn, BLn) respectively are programmed. Since the Q terminals of these eFuse memory cells are directly connected to the programming power supply VDDQ, their distances to the programming power supply are almost the same, and the voltage drop (IR-drop) across all memory cells are almost the same.

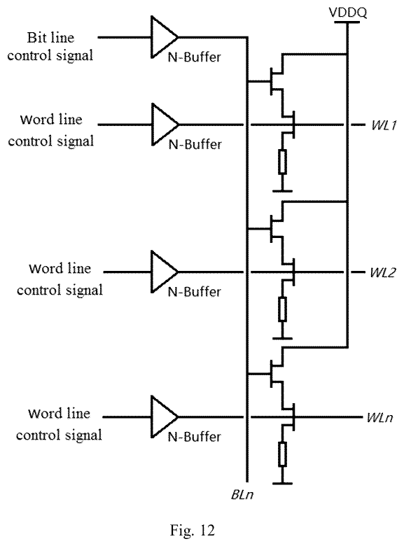

In the eFuse memory array in the Embodiment 3, as shown in FIG. 12, the driving modules (N-buffers) of the MOS tubes in all eFuse memory cells have the same driving ability, and the driving circuits of bit lines and word lines are identical. Thus, the circuit and layout design are simplified, the overall area is reduced, and the reliability is improved, and different cell combinations can be formed conveniently in the eFuse memory array.

While the present disclosure is described above in some preferred embodiments, the present disclosure is not limited to those embodiments. Any modification, equivalent substitution, or improvement, etc. made under the spirit and principle of the present disclosure should be deemed as falling in the scope of protection of the present disclosure.

What is claimed is:

1. An eFuse memory cell, comprising a first selection transistor, a second selection transistor and a fuse-link, wherein
a gate terminal of the first selection transistor is used as a BL port;
a drain terminal of the first selection transistor is used as a Q port;
a source terminal of the first selection transistor is connected to a drain terminal of the second selection transistor as a SA port;
a gate terminal of the second selection transistor is used as a WL port;
a source of the second selection transistor is connected to one end of the fuse-link; and
the other end of the fuse-link is used as a gnd port.

2. The eFuse memory cell according to claim 1, wherein
the BL port is used for connecting a bit line;
the Q port is used for connecting a programming power supply;
the SA port is used for connecting a sense amplifier;
the WL port is used for connecting a word line; and
the gnd port is used for grounding.

3. The eFuse memory cell according to claim 1, wherein
the first selection transistor and the second selection transistor are NMOS tubes.

4. The eFuse memory cell according to claim 1, wherein
substrate terminals of the first selection transistor and the second selection transistor are short-circuited to their respective source terminals.

5. The eFuse memory cell according to claim 1, wherein
the first selection transistor and the second selection transistor have the same size and structure.

6. The eFuse memory cell according to claim 1, wherein
the first selection transistor and the second selection transistor in the eFuse memory cell are manufactured through a Gate-All-Around process.

7. A memory array consisting of the eFuse memory cells according to claim 1,
comprising m rows and n columns of eFuse memory cells, where m and n are positive integers;
the Q ports of all eFuse memory cells are connected to the same programming power supply;
the WL ports of the eFuse memory cells in the same row are connected to the same word line;
the BL ports of the eFuse memory cells in the same column are connected to the same bit line; and
the SA ports of the eFuse memory cells in the same column are connected together and connected to corresponding sense amplifiers.

8. The memory array according to claim 7, wherein
m and n are greater than 1.

9. The memory array according to claim 7, wherein
m is equal to 2 R, n is equal to 2 Q, and R and Q are positive integers.
